(19) United States
(12) Patent Application Publication
(10) Pub. No.: US 2006/0179397 A1
(43) Pub. Date: Aug. 10, 2006

(54) Interface for generating an error code

(76) Inventors: Christian Stocken, Munchen (DE); Youssef Gannoune, Munchen (DE)

Correspondence Address: EDELL, SHAPIRO & FINNAN, LLC, 1901 RESEARCH BLVD., SUITE 400, ROCKVILLE, MD, 20850, US

(21) Appl. No.: 11/300,596

(22) Filed: Dec. 15, 2005

(30) Foreign Application Priority Data
Dec. 15, 2004 (DE) 102004060368.5

(51) Int. Cl. G11C 29/00

(52) U.S. Cl. 714/763

(57) ABSTRACT

An error code is generated by generating error correction data from a data sequence. These error correction data together with the data sequence are then written to a memory unit so as to be read from the memory unit. During the reading or during the writing, one bit in the data sequence has its content changed. This induces a bit error from which an error code is generated which can be clearly associated with the bit error. An interface arrangement can be inserted between a computer and a memory module. The interface arrangement contains data lines that are coupled to an apparatus which is designed to generate bit errors during a write or read operation.

### CROSS REFERENCE TO RELATED APPLICATIONS

This application claims priority under 35 USC §119 to German Application No. DE 10 2004 060 368.5, filed on Dec. 15, 2005, and titled “Method For Generating An Error Code, Interface Arrangement and Use Thereof,” of which are hereby incorporated by reference.

### FIELD OF THE INVENTION

The present invention relates to a method for generating an error code. The invention also relates to an interface arrangement and the use thereof.

### BACKGROUND

Modern computer systems today have volatile memories with sizes of 512 Mbytes and more, called RAM (Random Access Memory) for simplicity. The size of the total RAM in a computer system is dependent on the size of one or more memory modules which have been plugged into memory module slots on the motherboard of the computer system. The memory modules themselves in turn have a plurality of memory blocks arranged on them, each of which contains several million memory cells. Examples of memory blocks or memory chips include SDRAM or DDR SDRAM (“Double Data Rate Synchronous Dynamic Random Access”, read/write memory) memory chips, and examples of modules include DIMM (“Dual Inline Memory Module”), SDRAM or DIMM DDR SDRAM modules.

At the same time, modern application software is becoming increasingly more complex and requires ever more memory for execution on a computer system. The rising complexity can result in an error in a memory cell within a memory block in a module causing the application software to crash and possibly necessitate the entire computer system being restarted. It is therefore typical to use error correction methods, known as ECC (Error Correction Code) methods.

The error correction methods are able to identify and correct erroneous memory cells within the blocks of the memory module in a computer system, or what are known as bit errors. Bit errors are subsequently understood to mean a content in a memory cell which is different than the intended content. Bit errors can be generated by erroneous or particularly susceptible memory cells in the block. Alternatively, random discharges in the memory cell can result in bit errors.

More recent correction methods allow not only the correction of a single-bit error but also detection of a “2-bit error”, where two cells within a prescribed memory area of the memory module in the computer system do not have the intended content. Such methods are called SECDED (Single Error Correction Double Error Detection) methods.

Modern computer systems have memory controllers which undertake the control of the memory blocks and of the memory modules, that is to say essentially write or read data to or from the modules. In addition, the memory controllers use ECC or SECDED methods and can automatically detect and correct single bit errors. In addition, appropriate information about so called error codes are written to internal registers for later evaluation. FIG. 11 shows a known computer system 100 of this type.

The system 100 of FIG. 11 contains a central processor unit 101 (CPU) connected to a memory controller 102 via an internal memory bus 106. The processor 101 asks the memory controller 102 for data for further processing or provides it with data that is intended to be stored in the memory. The memory controller 102 is thus used as an interface between the central processor unit 101 and further memory modules which store the data provided for processing.

To this end, the memory controller 102 is connected to memory modules 104 and 105 via an interface called a bus. The memory controller 102 controls and regulates both read access and storage access to the individual memory modules 104 and 105, to the memory blocks in the modules and to the individual memory cells.

Such a memory module 104 is shown schematically in FIG. 9. The memory module 104 has individual memory blocks 114, 144 which are arranged next to one another on a support plate. The memory blocks are also called memory chips. The memory module 104 includes suitable connection contacts 134 which can be used to connect it to a corresponding memory module slot on the motherboard of the chip card module 100. The present memory module 104 in FIG. 9 contains eight individual memory blocks 114 with a respective fixed memory size of, for example, 64 Mbytes.

In addition, a further memory block 144 of identical design is provided. This is used to store the error correction data (ECC data) that is generated by the memory controller 102 and which allow the memory controller 102 in the computer system 100 to check the data stored in the remaining memory blocks 114 for errors and to correct these when appropriate. A further small chip 124 is used to store internal operating parameters. Examples of these are latency, “burst length” and the time before refreshment is required (refresh time).

An overview of motherboards with memory controllers and also of memory modules of various sizes can be found in the relevant computer periodicals, e.g. CT, Magazin für Computertechnik 21, 10.04.2004.

FIG. 10 shows some signals which the memory controller 102 in the computer system 100 transmits to a memory module 104 for read or write access. The signals CK and \overline{CK} are the clock signal and the inverted clock signal. For a read instruction, the command “Read” is transmitted from the memory controller to the memory module on a “Command” instruction line. At the same time, individual memory cells which are to be read are selected by signals on address lines “Address”. After a latency of two clock cycles CL=2, the content of the selected memory cells is present on the data line DQ. The data pulse on the data line DQ is in sync with a pulse on a data clock line DQS.

In the exemplary embodiment shown in FIG. 10, the command “Write” appears on the instruction line after 4 clock cycles of the clock signals CK and \overline{CK} for the purpose of writing data to the memory cells. At the same time as the write command, the corresponding memory bank BAa and the cell column COLb are selected on the address lines. A write operation for the data on the data line DQ is in sync with a rising or falling clock edge on the data clock line DQS. In other words, a data item which is present on the data line DQ is written to a memory cell upon every rising or falling clock edge on the data clock line DQS. In this context, the term data item means a signal which represents either the logic value 0 or the logic value 1. As described below, the term data item describes the value 0 or 1. A data item is therefore also a bit.

In this case, read access and storage access to the memory cells are effected as a burst, i.e. a number of memory cells are read and their contents are output sequentially on the data line DQ. In the same way, the data to be stored are applied sequentially to the data line and are thus stored in successive memory cells. The number of data items to be read or written is called the burst length. A burst length of 4 or 8 bits is usual in more recent memory blocks.

Since write access always involves all the memory blocks in the memory module being accessed, the memory controller 102 requires the associated requisite number of bits which are to be stored. With a burst length of 4 bits, 32 bits are stored in each memory block 114 of a memory module per write access operation. This is done 4 bits at a time on a total of 8 data lines DQ per memory block. This results in a total number of 256 bits which are written or read from the memory controller 102 to the memory module 104 per storage or read access operation. The number of bits which are to be written or read at the same time in each case is also called the cache line.

The memory controller 102 accordingly reads an entire cache line of 256 bits from the corresponding memory module 104. Similarly, a full cache line is always written to the module. Besides the actual useful data in the cache line, the write operation is additionally used to write error correction data to the memory block 144 in the memory module 104. The memory block 144 is thus used to hold error correction data for the respective cache line which is to be written. These error correction data, which are also called ECC data, are calculated in the memory controller 102 using the data of the cache line and are written to the module together with the cache line.

In the case of a read operation, the error correction data are read from the memory block 144 again. The error correction data can be used to identify any bit error in the cache line, that is to say a data item or bit with the wrong content, and to correct it if appropriate. In such a case, the memory controller 102 generates an error word and stores it in a register 103. From the error word, known as the “ECC syndrome”, the manufacturer of the memory controller can obtain information about the relevant data line and the position within a burst at which the erroneous bit has occurred. The ECC syndrome allows inferences about the location of the bit error, in the form of the data line, and the time in the form of the position within the burst.

The error word, or ECC syndrome, is not always the same for identical errors, but rather is dependent on the error correction mechanism used and hence on the manufacturer of a memory controller. It is thus necessary to know the precise error correction mechanism. If the error correction mechanism is not known, however, the ECC syndrome cannot provide any knowledge about the data line or the position in the burst at which the error has occurred.

### SUMMARY

It is an object of the invention to provide a method for generating an error code which allows the error code to be associated with a bit error.

It is a another object of the invention to provide an interface arrangement which allows later association of a single bit error with the error word generated by the memory controller. It is likewise an object of the invention to provide a use for such an arrangement.

The aforesaid objects are achieved individually and/or in combination, and it is not intended that the present invention be construed as requiring two or more of the objects to be combined unless expressly required by the claims attached hereto.

In accordance with the present invention, a method for generating an error code comprises: providing a volatile memory module including a number of memory cells; preparing to write a data sequence including a number of data items to the volatile memory module; generating error correction data from the data sequence and preparing to write the error correction data to the volatile memory module; writing the data sequence to the volatile memory module; writing the error correction data to the volatile memory module; reading the data sequence from the volatile memory module; reading the error correction data from the volatile memory module; checking the data sequence that has been read for errors in the data sequence using the error correction data; creating an error code when an error in the data sequence which has been read; and, during the writing or reading of the data sequence, altering the content of at least one bit in the data sequence.

The method of the present invention thus involves first generating error correction data from the unaltered data, or the intended data. The error correction data are also called the checksum. They can be used to determine an erroneous bit in the data sequence at a later time and to correct it if appropriate. The data sequence is then written to the memory together with the error correction data and is then read again. In addition, during the writing of the data sequence to the memory or during the reading of the data sequence from the memory the data sequence is altered and a bit with a different content is generated within the data sequence which is to be written or read. The actual data sequence is thus altered in a targeted manner by a bit error.

Error correction data in the unaltered data are likewise written to the memory. The subsequent step of comparing the data which have been read with the error correction data provides a bit error which is clearly associated with the alteration in the data sequence. This generates a corresponding error code which contains information about the bit error, for example the precise position of the error in a data sequence which has been read.

Alternatively, the data sequence can be read from the memory and, during the reading, a bit error is generated in a targeted manner. In both scenarios, a check is performed with the error correction data, where the altered data rather than the unaltered data is used. The error code generated by the error correction mechanism is thus clearly associated with the bit error which is obtained as a result of the alteration in the data sequence.

The steps can be repeated, with every repetition involving a different bit in the data sequence having its content altered. A table with all the error codes is thus created which contains each error code with an associated known bit error. Once the table has been fully created, it is possible to use an error code to infer the bit error even without knowledge of the error correction mechanism.

In another embodiment of the invention, a test data sequence with a prescribed data content is provided that includes a number of bits. This data sequence is prepared for the purpose of writing to the volatile memory module. The stipulated data sequence is known, which means that precise inferences regarding the error code generated are possible. In one expedient form, all the bits apart from one bit in the data sequence have the same value.

It is expedient if all the bits apart from one bit in a data sequence, or data burst, which is to be written have the same data item and hence the same content. The alteration step now changes this one bit, so that after the alteration step all the bits have the same content. This generates a single bit error within the data stream.

A read or write operation for the error correction data and the data sequence can take place at the same time or in parallel. Naturally, successive read or write operations are also possible, with the error correction data or the data sequence being read or written first, depending on the form.

In accordance with another embodiment of the invention, an interface arrangement comprises a support that includes a first connector device and a second connector device arranged on the support. The first connector device is suitably configured to hold a memory module that includes a first memory block and at least one second memory block with a plurality of addressable memory cells. The second connector device is suitably configured to plug into a memory module slot in a computer system, the computer system comprising a memory controller that is designed to interchange data with the memory module via the memory module slot. On the support there is at least one address line and an instruction line that is connected to the first and second connector devices. In addition, a plurality of data lines is provided, the data lines being designed or configured to transmit data to the memory module for storage in addressed memory cells or to transmit data from addressed memory cells in the memory module to the memory controller. The data are coded in signals, that is to say are represented by them.

An apparatus is provided that is coupled to at least one of the data lines. The apparatus including a node, a switching device between the node and a tap and at least one data line comprises a control unit with a control input and that is designed to output a pulsed actuating signal to the control connection of the switching device on the basis of a signal which is applied to the control input.

In accordance with the invention, the apparatus allows a data stream from the memory module to the computer system or from the computer system to the memory module to be altered selectively. This allows artificial bit errors to be generated within a data sequence, preferably a burst, and the precise knowledge of these artificial bit errors makes it possible to obtain a relationship between the bit error and an error word generated by the memory controller. The interface arrangement thus includes an apparatus which is designed for controllably generating single bit errors during a read or write operation between computer system and memory module.

Alteration of signals on the data line can be achieved based upon instructions on the instruction line. This is achieved by coupling the apparatus to the instruction line. It contains a sensor to detect predetermined command signals on the instruction line. By way of example, the sensor is designed to detect a read or write command. In one embodiment, the data are altered only in the event of write access. Alternatively, it is possible to alter data in the event of a read operation, in which data are read from the memory module to the computer system, and to generate a bit error in this way.

To alter signals on the data line, the apparatus can be designed to output a temporally limited pulsed signal to the at least one data line. The output from the occurrence of a signal on the instruction line may be in controllable form, the signal on the instruction line being a command for reading data from the at least one memory block or for writing data to the at least one memory block. The temporally limited pulsed signal thus masks the correct value or the correct data item and overwrites it with a new data item producing the bit error.

In a further embodiment of the invention, the apparatus contains an input to supply a control signal for the time control for a signal alteration or a programming input to supply a program data stream. The apparatus can contain a memory which is coupled to the programming input and which can be used to store control parameters. The apparatus is thus advantageously designed for precise time control for the data alteration.

The apparatus can control a switching device which takes a control signal from the apparatus as a basis for applying a potential, preferably a supply potential or a ground potential, to the data line which is connected to the switching device. In one embodiment, each of the data lines comprises a tap coupled to a respective switching device which can be controlled by the apparatus. In another embodiment, a resistor is provided between the signal device and the node that supplies the potential in order to avoid too large a flow of current. This reduces current loading on the memory module or the memory controller in the computer system.

In another embodiment, the switching devices which can be controlled by the apparatus are designed with field effect transistors.

The inventive interface arrangement can be used in a computer system, with the interface arrangement being arranged between a memory module and a memory module slot in a computer system. It is used to test an error correction word. In particular, it can be used for error analysis and for determining an error word on the basis of the appropriate bit error.

The inventive interface arrangement thus makes it possible to ascertain the association between a bit error on a data line at a particular position within a data burst and the corresponding error word or ECC syndrome without precise knowledge of the error correction mechanism within a memory controller.

The above and still further objects, features and advantages of the present invention will become apparent upon consideration of the following detailed description of specific embodiments thereof, particularly when taken in conjunction with the accompanying drawings where like numerals designate like components.

### BRIEF DESCRIPTION OF THE DRAWINGS

FIG. 1 depicts an exemplary embodiment of an interface arrangement that is connected between a computer system and a memory module in accordance with the present invention.

FIG. 2 depicts a schematic illustration of a first embodiment of the interface arrangement with a memory module connected thereto in accordance with the present invention.

FIG. 3 depicts a schematic illustration of a second embodiment of the interface arrangement with a memory module connected thereto in accordance with the present invention.

FIG. 4 depicts a flowchart of a first exemplary embodiment of a method of generating an error code in accordance with the present invention.

FIG. 5 depicts a flowchart of a second exemplary embodiment of a method of generating an error code in accordance with the present invention.

FIG. 6 depicts a flowchart of a third exemplary embodiment of a method of generating an error code in accordance with the present invention.

FIG. 7 depicts a signal-time diagram for various signals in accordance with an exemplary embodiment of the present invention.

FIG. 8 depicts a detail from a memory cell array of a memory block from the interface arrangement of FIG. 1.

FIG. 9 depicts a known memory module with a plurality of individual memory blocks.

FIG. 10 depicts a signal-time diagram for various signals for controlling the memory module of FIG. 9.

FIG. 11 depicts a known computer system with a memory controller and a memory module.

### DETAILED DESCRIPTION

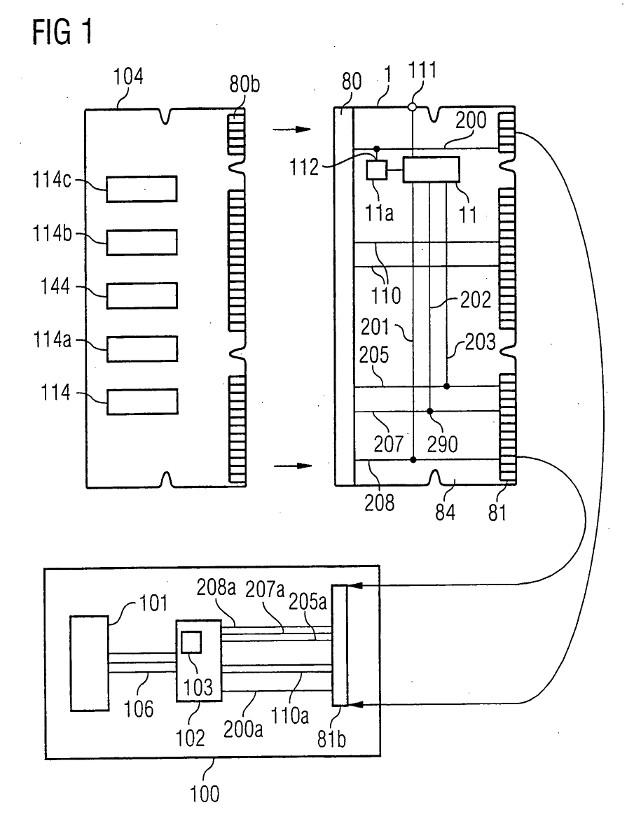

FIG. 1 shows an interface arrangement 1 in accordance with the present invention, where the interface arrangement is connected between a memory module slot in a computer system 100 and an additionally connected memory module 104. The computer system 100 includes a main processor 101 that is connected to a memory controller 102 via a bus. The processor 101 asks the memory controller 102 for data for processing or transmits data which are provided for storage in a memory module. The main processor 101, bus 106 and memory controller 102 are arranged on a support on the motherboard.

The motherboard likewise holds a memory module slot 81b which, in a normal mode of operation, has a memory module 104 plugged into it. The memory module 104 is actuated by the memory controller 102, which obtains the parameters required for actuation from the memory module 104. The memory controller 102 undertakes and accordingly regulates the interchange of data between the main processor and the memory module. To this end, it is connected to the slot 81b via data lines 205a, 207a, 208a, via address lines 110a and via instruction lines 200a. The memory controller can use the slot to store data in memory slots or to request data from the module.

In the exemplary embodiment shown in FIG. 1, the interface arrangement 1 is connected between the memory module slot 81b and the memory module 104 using a first connector 81 and a second connector 80. The first connector 81 is plugged into the memory module slot 81b and is attached thereto. The second connector 80 forms a memory module slot into which the memory module 104 is plugged.

In addition, various data lines 205, 207, 208, address lines 110 and instruction lines 200 are provided which connect the respective connection pins of the first connector 81 and the second connector 80 of the interface arrangement 1 to one another. This allows the memory module 104 to be monitored and controlled by the memory controller 102.

In this exemplary embodiment, the memory module 104 contains four individual memory blocks 114, 114a to 114c. These each have a plurality of addressable memory cells in which the memory controller 102 respectively stores data and reads them therefrom. A further memory block 144 of identical design is provided for the error correction data generated by the memory controller 102. The memory blocks are connected to the connector device 80b. The connection pins of the connector couple the individual memory blocks to the data lines 205, 207 and 208, the address lines 110 and the instruction lines 200.

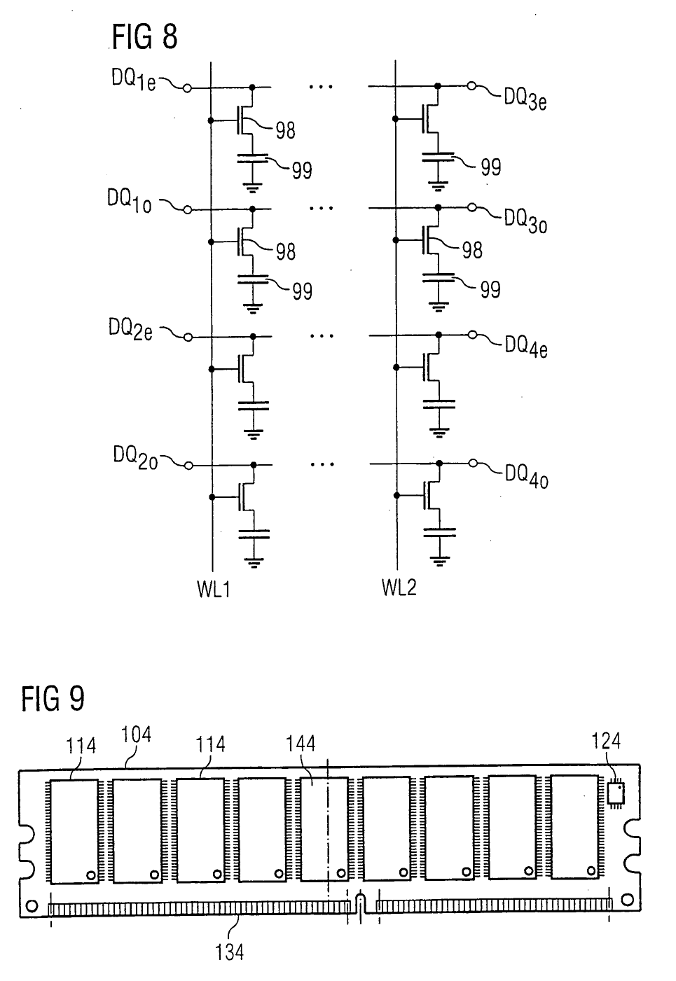

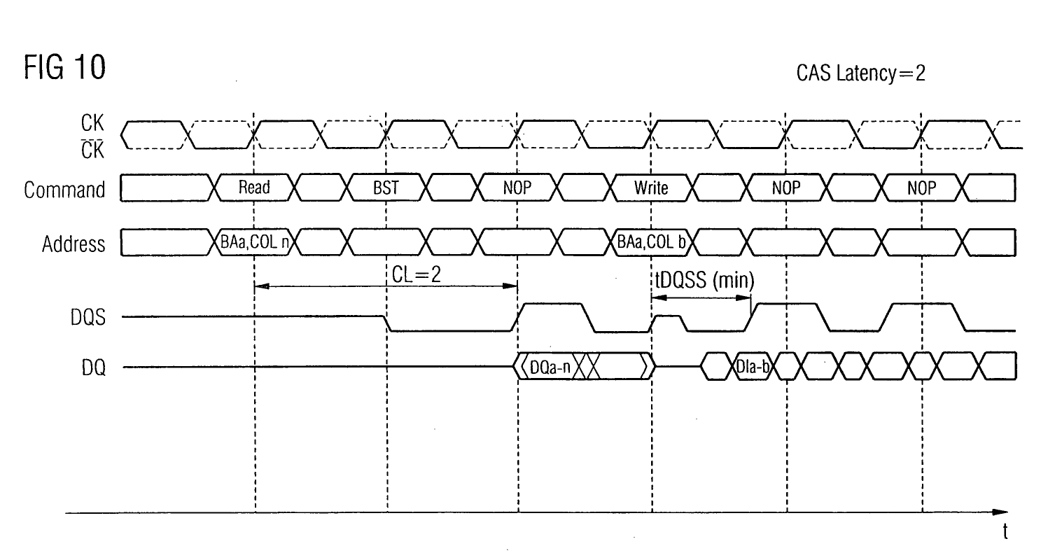

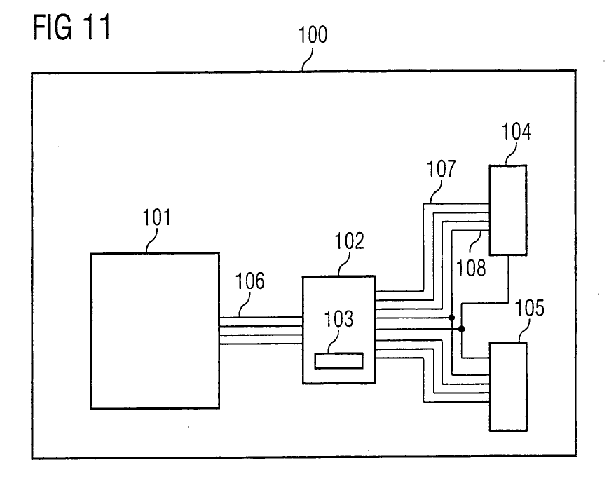

FIG. 8 shows a detail from a memory cell array in a memory block 114 or 144. The individual memory cells in this arrangement are arranged at the crossover points of word lines WL1, WL2 and bit lines DQ1, DQ2. Each memory cell comprises an actuating transistor 98 and a storage capacitor 99. Depending on the quantity of charge stored in the capacitor 99, the memory cell has the logic value 1 or 0. To actuate individual memory cells within the array, one of the word lines is actuated. The word line is prescribed by an address and is coupled to the address lines 110. Following actuation, all the selection transistors connected to the word line are open. The content of the memory cell can now be read on the bit or data lines DQ. Alternatively, it is possible to apply a charge to the memory cell. This writes information to the memory cell. Following a read or write operation, the memory cell is closed again.

For memory access for the purpose of writing data, the memory controller 102 sends an appropriate write command “Write” on the instruction lines 200a and 200, the write command being used by it to indicate to the module and the memory blocks 144 to 144c that data for writing are present on the data line. At the same time, the address line 210 is used to indicate the address of the memory cells to which the data which are present on the data lines 205, 207 and 208 are intended to be written. The signals on the address line select a number of memory cells in the memory blocks 114, 114a to 114c. Following the appropriate write command “Write” on the instruction line 200, the memory controller 102 applies the data intended for storage in the addressed cells to the data lines 205 to 208 after a short waiting time.

The data to be written are applied as a data sequence. A data sequence is also called a data burst. The write access thus involves not just one bit but rather a series of bits being written to various memory cells. The length of the burst is 8 bits in the present exemplary embodiment. Thus, 8 bits are written to 8 memory cells in the memory blocks 114 to 114c on each data line per burst.

The operation will now be outlined coarsely in FIG. 8 using an exemplary embodiment. As mentioned above, the data in the data burst arrive at the memory sequentially. There, they are briefly buffer-stored so that they can be processed in parallel. The buffer-storage is performed in registers which are connected to a multiplexer for the parallel processing. A logic circuit ensures that the correct word lines and bit lines, in which the data in the data burst are intended to be stored, in a memory cell array are actuated.

FIG. 8 shows a detail from the memory cell array with two different word lines WL₁ and WL₂. Each word line includes a plurality of memory cells, each with a selection transistor 98 and a storage capacitor 99 connected to it. A memory cell is selected by activating a word line WL. Following such activation, all the storage capacitors coupled to the word line are open, which means that their contents can be read or written on the connected bit lines DQ₁e to DQ₄o.

For a read or write operation, the word lines WL1 and WL2 are actuated at the same time. The selection transistors and storage capacitors coupled to the word lines are physically situated in different subregions of the cell array. By way of example, all the memory cells connected to bit lines Dqₓe are in a first subregion and the others in a second subregion. Actuating the word lines opens all the connected memory cells. For a write operation, a respective data item which is to be written from the data burst is then applied to the bit lines. In this case, the bit lines are coupled to outputs of the multiplexer, which now forwards the data in the sequential data burst to all the bit lines in parallel and at the same time. By way of example, only the data item which is at an even position in the data burst, that is to say at the 0^{th}, 2^{nd}, 4^{th} and 6^{th} positions, is applied to the bit lines DQ₁e to DQ₄e. The bit lines DQ₁o to DQ₄o carry a respective data item from an uneven position in the data burst. The write operation takes place at the same time. Following the write operation, the word lines WL₁ and WL₂ are closed again and a refresh or precharge is performed if appropriate.

In the case of a read operation, actuation of the word lines WL₁ and WL₂ accordingly opens the connected memory cells at the same time and routes the content onto the bit lines. A demultiplexer then processes the parallel data into the sequential data burst.

All read and all write access involve the use of all the memory blocks 114, 114a to 114c in the memory module 104. The result of this is that not single bits but rather a respective plurality of bits—in the present exemplary embodiment with a burst length of 8 bits, a total of 8*64=512 bits—are written. The 512 bits to be written are the cache line which the controller writes to the memory module. The use of a clock cycle of approximately 200 MHz and read and write operations on rising and falling clock edges of a clock signal result in a time period of approximately 2.5 ns per read or write operation, i.e. the whole cache line is written in 8*2.5 ns.

Besides the actual useful data, the error correction data calculated from the useful data by the memory controller 102 are also written to the memory 144. The error correction data allow the data to be checked to determine whether they have been read correctly. They thus also act as a checksum. Furthermore, they allow correction of a single bit error on each data line and using each position in the data burst which has been written.

The memory controller 102 therefore generates the error correction data not only on the basis of the data line but also using the position within the data burst. Error correction data are therefore generated both using space in the form of the existing data lines and using time in the form of the position within the burst.

When a bit error occurs during a read operation, the precise data line and the position within the burst can thus be ascertained. This ascertained information is written to a register 103 in the memory controller 102 shown in FIG. 1, the register being designed to be able to be read via an output. If the algorithm for error correction data in the memory controller 102 is known, the error value which is stored in the register and which is called the ECC syndrome can therefore be used to ascertain the data line and the precise position in the burst and hence the erroneous memory cell.

If, on the other hand, the algorithm of the memory controller 102 is not known, no further information about an error within the memory module 104 can be obtained from the ECC syndrome stored in the register. The proposed solution therefore provides for the individual data items to be manipulated on the data lines in targeted fashion, in order to obtain an association between the register value in the register 103 and a specific single-bit error. Once the association has been ascertained fully for each data line and each position in the burst, the association can be used to examine further modules for errors.

To this end, the interface arrangement I shown in FIG. 1 includes an apparatus 11a, which for its part is connected to a control and programming input 11. The apparatus 11a includes an input 112 which is coupled to the instruction line 200 via an appropriate line. The apparatus 11a is designed to detect appropriate instructions on the instruction line 200. By way of example, it is able to identify the commands “Write” and “Read” which initiate a write or read operation.

In addition, the control device 11 is coupled to the appropriate data lines 205, 207 and 208 via lines 201, 202 and 203. These lines 201 to 203 can be used to supply the data lines 205, 207 and 208 with signals which manipulate the actual signals which are present on the data lines and in this way result in a specific bit error on the corresponding data line.

If this targeted manipulation is effected at a particular time during a read or write burst, a bit at a specific position in the burst is altered on the basis of the respective data line. To this end, the apparatus 11 uses the instruction connecting line 204 to detect an appropriate command “Write” or “Read” on the instruction line 200. When a command appears, it sends a signal via the appropriate control line 201, 202 or 203 to the respective data line at a particular time on the basis of its programming.

As a result, during a write operation an incorrect data item is written to the corresponding memory cell in the memory module 104. During a subsequent read operation, instead of the correct data item an incorrect data item is transmitted to the memory controller 102. A subsequent check using the correct error correction data from the error correction chip 144 reveals an erroneous bit on the basis of the data line and the position in the burst. From this, the error correction device 102 generates an error value or ECC syndrome and stores it in the register 103.

Systematic generation of a bit error on each data line and for each position in the burst allows the error values generated and stored in the register 103 to be clearly associated with the data lines and the positions within the burst.

FIG. 7 shows a signal-time diagram for a burst sequence of burst length 8 with various data on the data lines DQ1 and DQ4. In the present embodiment, a burst upon a rising and a falling clock edge on the signal line DQS involves a data item being written to an addressed memory cell or read from the addressed memory cell. By way of example, in the second curve shown, the burst positions T0 and T2 to T7 respectively have the data item 0 being written to the memory cells addressed there, while the burst position T1 has the data item 1 being written to the cell there. The entire data sequence in this burst on the data line DQ1 is accordingly 01000000.

The interface arrangement of the present invention now masks the burst position T1 within the burst, as a result of which the data item 0 is now written to the addressed memory cell instead of the data item 1 originally provided. While the memory controller has calculated the error correction data with the bit sequence shown in curve 2, the bit sequence shown in curve 3 is written to the memory block on the data line DQ1. This results in an artificially generated error in the memory cell at the burst position T1. The error correction data are also written with the data. No manipulation takes place on any of the other data lines.

When the data which have been read are later read and checked, the memory controller 102 identifies that there is a bit error at this position. The bit error can be corrected using the error correction data which have likewise been read. In addition, the memory controller 102 generates an error code which indicates that a single-bit error has been identified and corrected at position T1 on the data line DQ1. The error code is stored in the register 103. This means that this error code in the register 103 can be clearly associated with the artificially generated error on the data line DQ1.

In the same way, the apparatus 11 and the inventive interface arrangement 1 also allow data to be altered on any other data line between the memory controller 102 and the memory module 104. Curve 4 shows the burst which is output by the memory controller 102 on a further data line DQ4. At the fifth position T4 in the burst, the data item 0 is intended to be written. The apparatus 11 masks this position while the data sequence is being written from the memory controller to the memory block, so that the data item 1 is written to the corresponding memory cell in the block instead of the data item 0. A subsequent read operation and a comparison between the error correction data and the data which have been read in turn result in an error, this time on the data line DQ4 at the position 5.

To perform such manipulation, it is necessary to alter the bit for manipulation within a short time. This may prove to be difficult, since clock cycles of 200 MHz and more are frequently achieved. The data item to be written is therefore present on the data line DQ only for the very short time of approximately 2.5 ns. Switches of appropriately high quality for manipulation are required in order to achieve sufficient switching speeds in the region of a few picoseconds. It is therefore expedient to provide special test sequences for data sequences which are to be written, the test sequences allowing manipulation even with switches of simpler design.

FIG. 7 shows such test sequences. Accordingly, all the positions in a burst apart from the position which is to be manipulated contain the same data item. In curve 2 on the data line DQ1, for example, the burst positions T0 and T2 to T7 contain the data item 0 and only the position T1 contains the data item 1. Correspondingly, only the burst position T5 on the data line DQ4 contains the data item 0, whereas all the other positions contain the data item 1. Instead of the term ‘burst position’ it is also possible to use the term ‘bit in the burst’. Bit T1 in the data burst is accordingly synonymous with burst position T1.

For manipulation purposes, it is relatively simple to pull the appropriate data line either to the data item 1 or to the data item 0 during the entire burst length and not just during the burst position which is to be manipulated. This can be done particularly easily using switches provided for this purpose, which apply either a first potential for the data item 0 or a second potential for the data item 1 to the appropriate data line. This can be done for the entire duration of the burst, since all the other positions in the burst have the same value.

The test sequences provided therefore make it possible to use simpler and not so time-critical circuits. Equally, the time of the switching operation is no longer so critical, since the switching operation needs to be performed only at a time at which the bit for manipulation is not already present on the data line. To manipulate the first or the last position within the burst, it is necessary to close the switches shortly before the start or to keep them closed until shortly after the end of the burst.

A further prerequisite for such manipulation is that the external driver, which is actuated by the apparatus 11, is more powerful than the data driver in the memory controller 102. It is thus necessary to ensure that for the manipulation the actual value to be written is suppressed by the external driver to a sufficient extent.

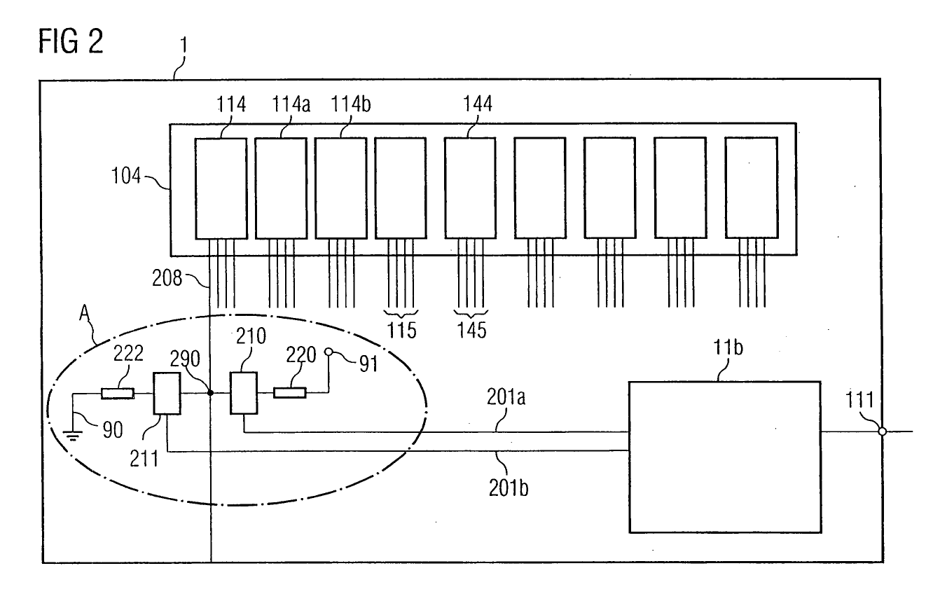

FIG. 2 shows a schematic illustration of a further exemplary embodiment of the interface arrangement 1. Components which have the same function or action bear the same reference symbols in this case. The memory module 104 with 8 data memory blocks and a checking block 144 is again connected to the interface arrangement 100 via an interface, as shown schematically. Data lines which are routed to the individual memory blocks 114, 114a, 114b in the memory module 104 are likewise shown schematically. One data line 208 is highlighted in particular.

In this exemplary embodiment, a control unit 11b is actuated by control signals at the input 111. A controller (not shown) uses these to send the appropriate parameters to the control unit 11b. The output of the latter has a plurality of control lines, two lines 201a and 201b of which are shown here. The two control lines 201a and 201b are routed to switches 210 and 211. These connect a tap 290 on the data line 208 via a resistor 220 or 222 to a connection 91 or 90 for a supply potential VDD or a ground potential. This pulls the data line 208 either to the ground potential or to the supply potential via the switches 210 and 222, depending on the signals on the control lines 201a and 201b. The time for closing or opening the switches 210 and 211 is set by the control signals.

The resistors 220 and 222 are required in order to allow a sufficient voltage drop between the respective potential and the driver (not shown here) in the memory controller 102 when the switches 210 and 211 are closed. This reduces the current loading on an internal signal driver in the memory controller.

Suitable methods are used to close one of the two switches upon a read or write command. The data line 208 is accordingly pulled to the appropriate potential for the entire duration of the data burst. It is expedient if, in this regard, a suitable test sequence is provided for the read or write operation on the appropriate data line.

The design section A including the resistors 220, 222 and the switches 210 and 211 needs to be generated for each data line in the memory module 104. Appropriate actuation of the control unit 11b thus allows manipulation of a single bit per data burst on each data line.

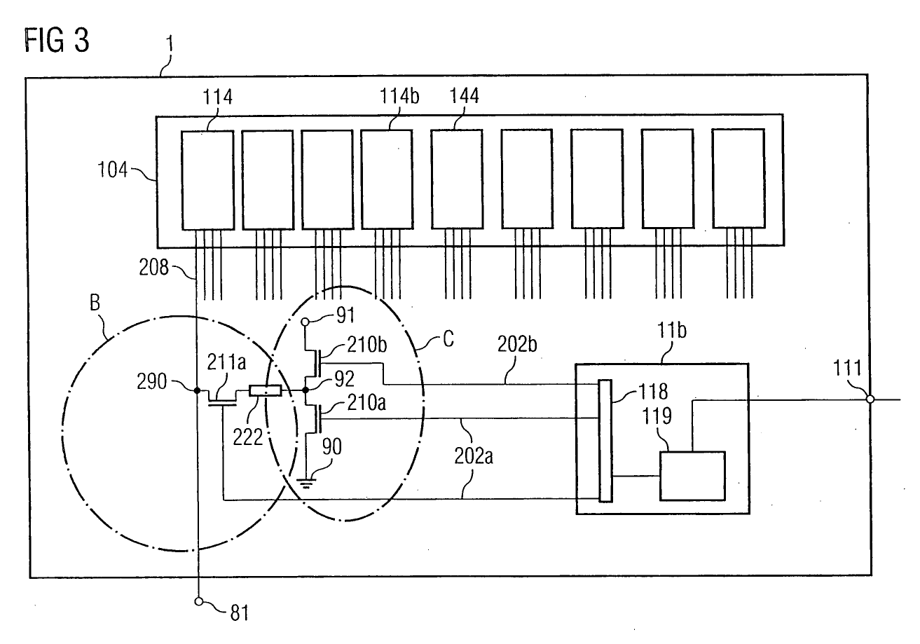

A further exemplary embodiment is shown in FIG. 3. In this case too, components which have the same action or function bear the same reference symbols. The embodiment shown allows a design with fewer resistors. The design section B contains a field effect transistor 211a, one connection of which is connected to the tap 290 and the other connection of which is connected to the resistor 222. A control connection of the transistor 211a is routed via the control line 202a to the control unit 11b.

The second connection of the resistor 222 is connected between the connections of two field effect transistors 210a and 210b. The respective other connection of the field effect transistors is connected to the supply potential connection 91 or to the ground potential connection 90. The control connections of the field effect transistors 210a and 210b are routed via the control lines 202b and 202c to the unit 11b. The design section C including the two field effect transistors 210b and 210a is required only once in this embodiment. The design section B including the field effect transistor 211a and the resistor 222 needs to be provided for each data line in the memory module 104 and the interface arrangement 1.

The control unit 11b in this refinement also contains a memory 119, which is connected to the programming input 111, and a controller 118. The memory contains data which are required for controlling the timing of the switching operation in the switches. This makes it possible to write a firm stipulation for various data sequences to the memory module and to perform the intended manipulations using the control unit 11b. The memory 119 has a data stream written to it via the programming device, so that the interface arrangement 1 can operate independently. The data stored in the memory 119 are required by the controller 118 in order to generate the necessary actuating signals and to output them to the control connections of the field effect transistors.

The parameters which have been transferred in the data stream and have been stored in the memory 119 include, by way of example, the position in the burst, the time before the data are present on the data line during read or write access, or else the burst length or burst duration.

It is possible to combine the two embodiments as desired. It is thus also possible to omit one of the two supply potential connections 90 or 91, for example. This makes sense particularly when the test sequences provided contain just one data item for each burst and each data line. It is likewise possible to connect a capacitor between the resistor 222 and one of the two connections 90 or 91 so as to allow a faster changeover operation.

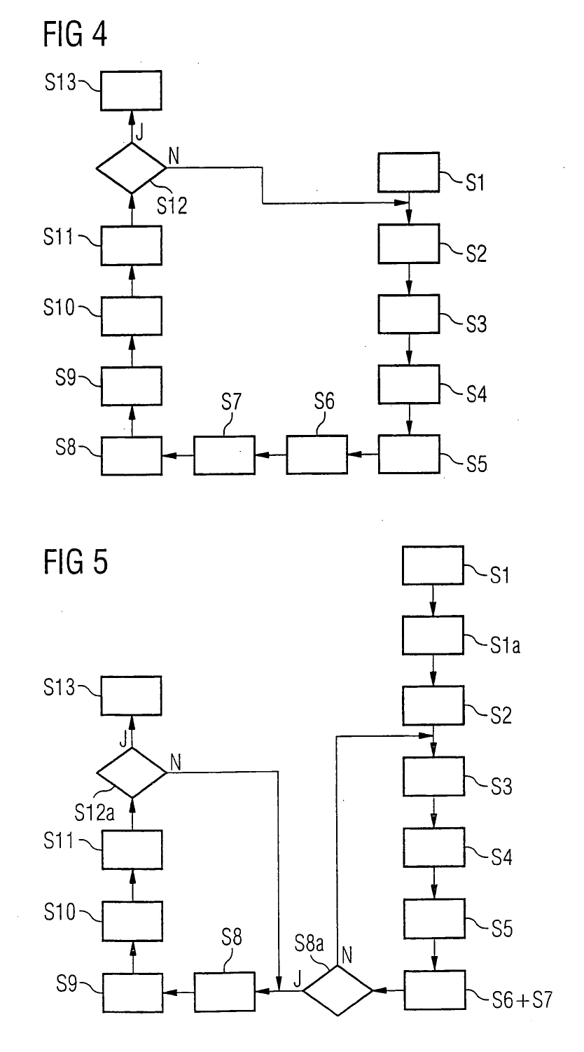

FIG. 4 shows a first exemplary embodiment of a checking method which can be used for clearly associating an error value ECC syndrome described by a memory controller with an artificially generated bit error. Step S1 of this method involves a memory module being prepared beside a computer system and a memory controller. The memory controller contains functions which calculate error correction data and a checksum from data which are to be written to the memory module and which transmit them to the memory module together with the data which are to be written.

In step S2, a known data sequence is generated. This may be a sequence of bits, for example, which all except one bit have the same data item or the same value.

In step S3, this data sequence is conditioned and combined into packets which are intended to be written to a memory module in a write access operation. This data packet is also called a cache line. In step S4, the error correction data are calculated from the cache line. Particularly in more recent memory systems, these data may be obtained not only from the number of data lines which are used to write the cache line but also from the position within the burst.

In this exemplary embodiment of the method, the data are sent from a memory controller to the memory module. This is done by outputting an appropriate command on the command line, which prepares the memory module for the subsequent data on the data line for writing to the appropriate memory cells. To this end, besides the “Write” command on the instruction line the appropriate address on the address lines is also transmitted to the memory module.

When a prescribed time t_{DQSS} has elapsed, the data are then applied to the data lines by the memory controller upon each rising or falling clock edge of a clock signal. The clock signal used is a data synchronization clock signal DQS. During this write operation, particularly before the data are actually stored in the memory cells, the data are altered. The data alteration, particularly the position within the burst, and the data line are known.

In step S6, the cache line with the altered bit is now stored in the memory cells. In step S7, the error correction data are also written to the memory. Step S7 can take place in parallel with and at the same time as step S6.

Next, the data written to the memory and the error correction data are read in step S8. Using the error correction data, the data which have been read from the memory cells are checked for errors in step S9. Since the data have been altered in step S5, this step results in a specific bit error. An error value can be generated from this in step S10. By way of example, the error value is stored in a register for processing later. The error value contains a coded representation of the information regarding the data line on which the error occurred, and the specific position within the burst. This matches the values for the manipulation of the data in step S5. The specific error value accordingly allows direct inference of the data line and the position in the burst. Conversely, it is possible to associate the error value generated if the data line and the position in the burst are known.

In step S11, the register is read and deliberately stored in a test program. In step S12, a check is performed to determine whether the test method has concluded. Should this be the case, further evaluation can take place in step S13. Otherwise, method steps S2 to S11 are repeated.

FIG. 5 shows an embodiment of the method in which the interface arrangement is programmed in advance on the basis of a manipulation which is to be performed. Method steps which have the same function bear the same reference symbols. In step S2, a test sequence is generated again. By way of example, this test sequence may be a series of zeros and ones. One bit in this series has had its value switched. In step S3, the data to be written are combined into a cache line again and the error correction data for the respective cache line are calculated in step S4. By way of example, in step S3 the cache line for the data which are to be written contains the data burst 01000000 for a data line DQ. For all the other data lines, the respective bursts contain just zeros.

In step S5, before this cache line is actually stored in the memory cells in the memory module, the data are altered such that only zeros are now written on the data line DQ1. During the actual write operation in step S6 and step S7, the data content on the data line is altered accordingly.

In step S8a, a check is performed to determine whether all the necessary data have already been written. In the present exemplary embodiment of the method, provision is made for not just one cache line to be written, but rather several. This means that upon every write operation for a cache line another data line at the same burst position can be manipulated or the same data line at another burst position can be manipulated, for example.

Further combinations in the manipulation are likewise possible. By way of example, it is also possible to manipulate a plurality of bits at the same time. This covers multibit errors on the data line.

In step S8, the data and the check data are read again. In step S9, the data which have been read are checked for errors, and single-bit errors are corrected as appropriate. At the same time, in step S10 an error word is generated which indicates the precise location and the position within the burst at which the error has occurred. In step S11, the register is read and the value is stored. A check is then performed in step S12a to determine whether the read operation has concluded, i.e. whether all the memory cells have been read. If this is the case, the process can continue in step S13. Should this not be the case, the method is repeated with steps S8 to S11.

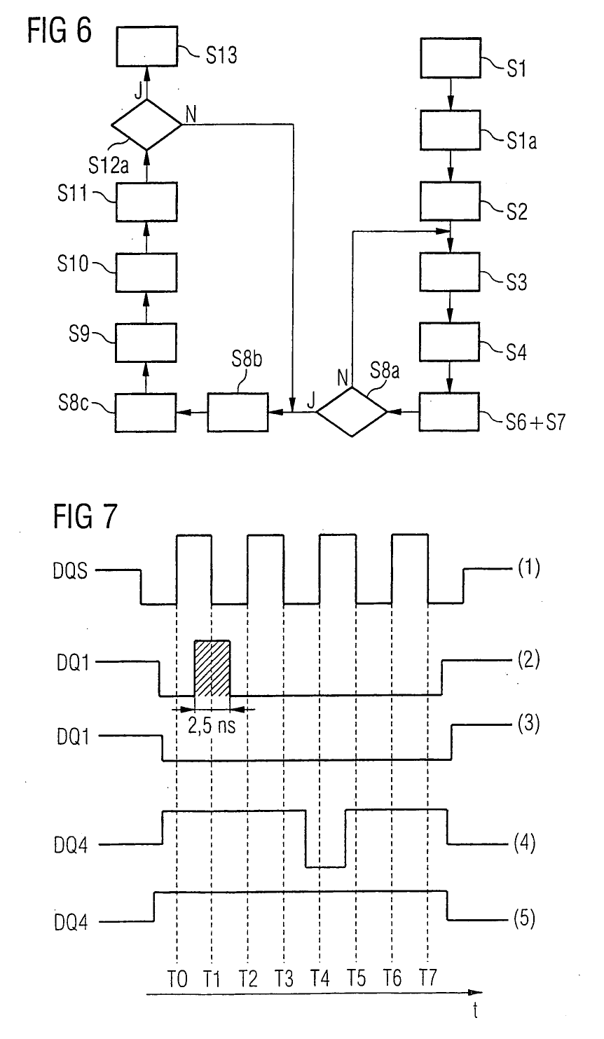

Instead of manipulating the data during the write operation in steps S5 and S6, it is likewise possible to manipulate the data during a read operation. FIG. 6 shows such an exemplary embodiment. In this case too, data are written to a memory module in a plurality of write cycles. When the storage operation has concluded, these data are read from the memory again in step S8b and are altered by the interface arrangement in the manner prescribed externally in step S1a. The data which have been read thus likewise have a bit error. In this case too, an error word is again generated in step S10 and is stored and output. The read operation is repeated in steps S8b to S11 until all the data formerly written to the memory are read again. Evaluation can then be performed in step S13.

The inventive interface arrangement and the method allow data to be manipulated during a write operation to memory cells in a memory module and during a read operation for the data contents from the memory cells in the module. In this case, the data are manipulated in line with a stipulation in such a way that the manipulation allows an association between a supposedly erroneous data line and an error that has been generated by the memory controller.

In the exemplary embodiments, this is done by expediently generating test sequences which allow simple implementation on account of lesser time stipulations. In principle, however, the interface arrangement allows any desired read or write operation to be manipulated and bit errors to be generated there. This requires the provision of suitably fast switches whose switching times are much shorter than the time for which a data item is present on the data line. This allows the data item to be manipulated. This switches similarly allow the data lines to be isolated from the other elements, for example the resistors.

Equally, data which belong to application programs can also be manipulated in targeted fashion during a read or write operation. Since the manipulation of the data lines and also the precise time of the manipulation within the burst are known, it is possible, regardless of the burst length and the number of data lines, to associate the error word generated by the memory controller with the supposedly erroneous data line and position within the burst. Manipulation can be performed on a plurality of data lines or at a plurality of positions within the burst at the same time. This means that it is possible to check whether the memory controller is able to detect a plurality of bit errors too. The interface arrangement may thus expediently be used for various manipulations on the data lines. The information obtained can be used for error analysis in memory modules or memory blocks. It becomes possible to test memory modules with memory controllers from various manufacturers.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### LIST OF REFERENCE SYMBOLS

1: Interface arrangement
100: Computer system
104: Memory module
101: Central processor
102: Memory controller
103: Register
114, 114a, 114b, 114c: Memory blocks
144: Error correction memory block
11: Apparatus
11b: Control unit
205, 207, 208: Data lines
200, 204: Instruction line
106: Bus
80,81: Interface
201, 202, 203: Control line
111: Programming input
112: Instruction input
119: Memory
210, 211: Switch
220, 222: Resistors
201a, 201b: Control lines
202a, 202b, 202c: Control lines
210a, 210b, 211a: Field effect transistors
290: Tap
90, 91, 92: Nodes, potential connections
98: Actuating transistor
99: Storage capacitor
A, B, C: Designs
S1, . . . , S13: Method steps
DQS: Data clock line
DQ1, DQ2, DQ4: Data line
WL1, WL2: Word lines

What is claimed is:

1. A method for generating an error code, comprising:
(a) providing a volatile memory module including a plurality of memory cells;
(b) preparing a data sequence having a number of bits to be written to the volatile memory module;
(c) generating error correction data from the data sequence, the error correction data being suitable for identifying a bit error in the data sequence;
(d) writing the data sequence to the volatile memory module;
(e) writing the error correction data to the volatile memory module;
(f) reading the data sequence from the volatile memory module;
(g) reading the error correction data from the volatile memory module;
(h) checking the data sequence that has been read for bit errors in the data sequence using the error correction data; and
(i) creating an error code based upon an ascertained bit error;
wherein, during step (d) or during step (f), the content of at least one bit in the data sequence is altered based upon a control signal.

2. The method of claim 1, further comprising:
(j) associating the error code with the at least one bit with altered content in the data sequence.

3. The method of claim 2, further comprising:
(k) repeating steps (b) to (j), wherein, during each step (d) or each step (f), the content of another bit in the data sequence is altered based upon a control signal; and
(l) creating a table that associates error codes with corresponding bits with altered content in the data sequence.

4. The method of claim 1, wherein step (h) comprises:
the checking step comprises:
(h.1) correcting the bit error in the data sequence that has been read using the error correction data.

5. The method of claim 1, wherein step (b) comprises:
(b.1) providing a data sequence including a plurality of bits, wherein all the bits except for one bit in the data sequence have the same content.

6. The method of claim 5, wherein, during step (d) or during step (f), the one bit that does not have the same content as all the other bits in the data sequence is altered, such that all the bits in the data sequence have the same content.

7. The method of claim 1, wherein steps (d) and (e) and/or steps (f) and (g) are performed at parallel times.

8. The method of claim 1, wherein step (d) comprises:
(d.1) providing signal lines to transmit the data sequence to the memory; and
(d.2) applying a signal representing a number of bits in the data sequence to one of the signal lines.

9. The method of claim 8, wherein the signal is altered during application of the signal in step (d.2) by applying a partially constant first or a second potential to the one of the signal lines.

10. An interface arrangement, comprising:
a support;
a first connector device arranged on the support and configured to hold a memory module;
a second connector device arranged on the support and configured to plug into a memory module slot in a computer system;
at least one address line that is arranged on the support and is connected to the first and second connector devices;
at least one instruction line that is arranged on the support and is connected to the first and second connector devices;
a plurality of data lines that are arranged on the support and are connected to the first and second connector devices, wherein at least one of the data lines includes a tap;
an apparatus comprising a node to supply a first potential;
a switching device that is connected between the tap and the node; and
a control unit including a control input to supply a control signal, wherein the control unit is connected to a control connection of the switching device and is configured to output a pulsed actuating signal to the control connection of the switching device based upon a signal that is applied to the control input.

11. The interface arrangement of claim 10, wherein the node is coupled to a first and a second potential connection.

12. The interface arrangement of claim 10, wherein the apparatus includes a sensor that is coupled to the at least one instruction line and is configured to detect predetermined command signals being transmitted on the at least one instruction line and to the control unit, and the control unit is further configured to output the pulsed actuating signal based upon a predetermined command signal.

13. The interface arrangement of claim 10, wherein the control unit includes a memory unit that is connected to the control input so as to store control values for setting a time for output of the pulsed actuating signal.

14. The interface arrangement of claim 10, further comprising:
a second controllable switching device that is connected between a second node that supplies a second potential and the tap, wherein the second controllable switching device includes an actuating connection that is connected to the control unit.

15. The interface arrangement of claim 14, wherein each of the first and second potentials is a supply potential or a ground potential.

16. The interface arrangement of claim 10, further comprising:
a resistor that is connected between the switching device and the node.

17. The interface arrangement of claim 14, wherein the switching devices comprise field effect transistors.

18. A computer system comprising the interface arrangement of claim 10 arranged between a memory module and a memory module slot in the computer system so as to connect the memory module to the memory module slot, wherein the interface arrangement is configured to generate a data error during transmission of data from a memory controller of the computer system to the memory module or from the memory module to the memory controller.
